(19) United States
(12) Patent Application Publication
(10) Pub. No.: US 2016/0273852 A1
(43) Pub. Date: Sep. 22, 2016

(54) COOLING DEVICE AND COOLING DEVICE OF ELECTRONIC APPARATUS USING MIXED WORKING FLUID

(71) Applicant: FUJITSU LIMITED, Kawasaki-shi (JP)

(72) Inventors: Nobuyuki HAYASHI, Yokohama (JP); TERU NAKANISHI, Isehara (JP); Yasuhiro Yoneda, Machida (JP)

(73) Assignee: FUJITSU LIMITED, Kawasaki-shi (JP)

(21) Appl. No.: 15/168,754

(22) Filed: May 31, 2016

Related U.S. Application Data
(63) Continuation of application No. PCT/JP2013/082618, filed on Dec. 4, 2013.

(51) Int. Cl. F28F 23/00; H05K 1/02; H05K 7/20; F28D 15/02

(52) U.S. Cl. CPC F28F 23/00; F28D 15/0266; H05K 1/0203; H05K 7/20154; H05K 7/20218; F28F 2250/08

(57) ABSTRACT

A cooling device comprising a heat receiver attached to a heat generating member and using a flow of coolant to rob heat from the heat generating member, a heat exchanger radiating off heat from the inflowing coolant to lower the temperature of the coolant, a first channel carrying the coolant from the heat receiver to the heat exchanger, a second channel carrying the coolant from the heat exchanger to the heat receiver, and a pump for making the coolant move, wherein, as the coolant, a mixed working fluid comprised of pure water or impure water containing nanoparticles plus ethanol to give an alcohol concentration of ethanol 0.1 mass % to 5 mass % is used to improve the freezing resistance.

### CROSS-REFERENCE TO RELATED APPLICATION

This application is a continuation application of International Application PCT/JP2013/82618 filed on Dec. 4, 2013, and designating the U.S., the entire contents of which are incorporated herein by reference.

### FIELD

The present application relates to a cooling device and a cooling device of an electronic apparatus using a mixed working fluid.

### BACKGROUND

Known in the art is a cooling device which cools an electronic component mounted in an electronic apparatus using a coolant (working fluid), for example, a heat pipe. Further, for the coolant, often a substance mainly comprised of water is used since water does not contribute to global warming and has a high cooling characteristic. A water-based working fluid for heat pipe use which uses mainly water and can improve the heat transport characteristic of a general use heat pipe is disclosed in Japanese Laid-Open Application Publication No. 2013-224770. Japanese Laid-Open Application Publication No. 2013-224770 discloses a working fluid of pure water plus an alcohol with three or more carbon atoms (0.01% to 20%) and nanoparticles.

However, a coolant mainly comprised of water expands in volume along with freezing of the water at the time of transport and storage in a cold environment, so the cooling device is liable to rupture upon freezing. Accordingly, while the working fluid disclosed in Japanese Laid-Open Application Publication No. 2013-224770 is improved in heat transport characteristic, it has no freezing resistance. It is not suitable as a working fluid for heat pipe use which is transported and stored in a cold environment.

Therefore, to prevent rupture due to freezing of a cooling device, a cooling device has been proposed which uses a coolant comprised of water plus ethanol as a mixed working fluid, seals this in the cooling device to lower the solidification point, and thereby improves the freezing resistance. For example, Japanese Laid-Open Application Publication No. 2005-42949 discloses a Stirling cooler using a coolant or water plus an additive containing ethanol or ethylene glycol. Further, Japanese Examined Patent Publication No. 63-12504 discloses a heat transfer device using a working fluid comprised of trifluoroethanol.

In the Stirling cooler disclosed in Japanese Laid-Open Application Publication No. 2005-42949, it is described to add to water an additive containing ethanol or ethylene glycol and make the ratio of the ethanol or ethylene glycol after addition of the additive in the coolant 20 wt % or less. However, if using a mixed working fluid with a ratio of ethanol or ethylene glycol in the coolant of close to 20 wt %, the fall in latent heat is greater than with water and there is the problem that the heat transport rate falls and, in a cooling device, the cooling performance falls. Further, the trifluoroethanol aqueous solution described in Japanese Examined Patent Publication No. 63-12504 is a working fluid for heater use and is not a working fluid for cooling device use.

### SUMMARY

According to a first aspect of the embodiments, there is provided a cooling device using a mixed working fluid comprising a heat receiver carrying a coolant to rob heat from a heat generating member, a heat exchanger transferring heat from the coolant and lowering the coolant in temperature, a first channel carrying the coolant from the heat receiver to the heat exchanger, and a second channel carrying the coolant from the heat exchanger to the heat receiver, wherein the coolant is comprised of pure water plus ethanol and has an alcohol concentration of ethanol 0.1 mass % to 5 mass %.

Further, according to a second aspect of the embodiments, there is provided a cooling device using a mixed working fluid comprising a heat receiver carrying a coolant to rob heat from a heat generating member, a heat exchanger transferring heat from the coolant and lowering the coolant in temperature, a first channel carrying the coolant from the heat receiver to the heat exchanger, and a second channel carrying the coolant from the heat exchanger to the heat receiver, wherein the coolant is comprised of an aqueous solution containing an additive plus ethanol and has an alcohol concentration of ethanol 0.1 mass % to 5 mass %.

According to a third aspect of the present embodiments, there is provided a cooling device of an electronic apparatus using a mixed working fluid cooling a heat generating member mounted on a printed circuit board, in which cooling device of an electronic apparatus, the cooling device comprises a heat receiver attached to the heat generating member and carrying a coolant to rob heat from the heat generating member, a heat exchanger arranged on the printed circuit board, a fan cooling the heat exchanger by cooling air, a first channel carrying the coolant from the heat receiver to the heat exchanger, and a second channel carrying the coolant from the heat exchanger to the heat receiver, the coolant comprised of pure water plus ethanol and having an alcohol concentration of ethanol 0.1 mass % to 5 mass %.

Further, according to a fourth aspect of the embodiments, there is provided a cooling device of an electronic apparatus using a mixed working fluid cooling a heat generating member mounted on a printed circuit board, in which cooling device of an electronic apparatus, the cooling device comprises a heat receiver attached to the heat generating member and carrying a coolant to rob heat from the heat generating member, a heat exchanger arranged on the printed circuit board, a fan cooling the heat exchanger by cooling air, a first channel carrying the coolant from the heat receiver to the heat exchanger, and a second channel carrying the coolant from the heat exchanger to the heat receiver, the coolant comprised of an aqueous solution containing an additive plus ethanol and having an alcohol concentration of ethanol 0.1 mass % to 5 mass %.

### BRIEF DESCRIPTION OF DRAWINGS

FIG. 1 is a view of the configuration illustrating the configuration of a cooling device using a mixed working fluid of the present application.

FIG. 2 is an equilibrium diagram illustrating a mixing ratio of an ethanol aqueous solution comprised of water plus ethanol and a state of solidification with respect to temperature.

FIG. 3 is a view illustrating a configuration of a measurement system of a cooling performance of a cooling device.

FIG. 4 is a state diagram illustrating a relationship between a concentration of an ethanol aqueous solution comprised of pure water plus ethanol and a cooling loss.

FIG. 5A is a view comparing enthalpy in the case where the cooling device illustrated in FIG. 3 has pure water sealed in it at an atmospheric pressure and in the case sealed in it at a reduced pressure state.

FIG. 5B is a view illustrating a magnitude of pressure (gauge pressure) when reducing the pressure of pure water and the results of measurement of the cooling unit performance (heat resistance) when making the heater of the cooling device illustrated in FIG. 3 500 W and making the air speed from the cooling fan 5 m/s.

FIG. 5C is a view illustrating a cooling performance ratio corresponding to the pressure (gauge pressure) of pressure reduction of the pure water illustrated in FIG. 5B.

FIG. 6A is a perspective view illustrating the structure of a CPU module to which the cooling device of the present application is applied.

FIG. 6B is a perspective diagram illustrating an electronic apparatus in which a plurality of CPU modules of FIG. 6A are mounted.

FIG. 7A is a state diagram illustrating a relationship between a concentration of an ethanol aqueous solution comprised of an aqueous solution of pure water containing an additive plus ethanol and a cooling loss.

FIG. 7B is a view illustrating the results of measurement of the cooling unit performance when using pure water and when using impure water in the state making the heater 35 of the cooling device illustrated in FIG. 3 500 W, making the air speed from the cooling fan 5 m/s, and making the ambient temperature 21° C.

### DESCRIPTION OF EMBODIMENTS

Below, using the attached drawings, embodiments of a cooling device and a cooling device of an electronic apparatus using a mixed working fluid according to the present application will be explained in detail based on specific examples. The present application provides a cooling device and a cooling device of an electronic apparatus using a mixed working fluid improving the freezing resistance of the coolant and using a cooling of a suitable ethanol concentration not causing a drop in the cooling performance.

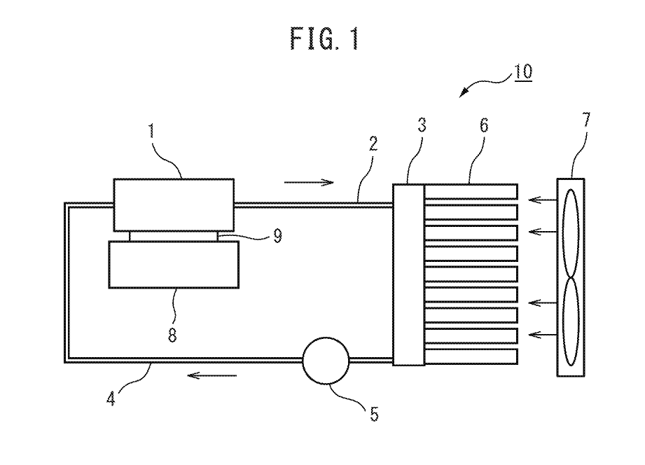

FIG. 1 illustrates the configuration of an embodiment of a cooling device 10 using a mixed working fluid of the present application. The cooling device 10 comprises a heat sink (heat receiver) 1 robbing heat from a semiconductor package or other heat generating member (cooled member) 8 by carrying a coolant comprised of a mixed working fluid and a radiator (heat exchanger) 3 radiating off heat from the mixed working fluid warmed by robbing the heat. The mixed working fluid warmed at the heat receiver 1 is sent from the heat receiver 1 to the heat exchanger 3 by a feed channel (first channel) 2. Further, the mixed working fluid lowered in temperature at the heat exchanger 3 is sent by a return channel (second channel) 4 from the heat exchanger 3 to the heat receiver 1.

Furthermore, in this embodiment, in the middle of the return channel 4, a pump 5 for making the mixed working fluid move is provided. Note that, if it were possible to obtain natural circulation utilizing the difference in elevation of the heat receiver 1 and heat exchanger 3 in their vertical arrangement and the difference in specific gravity between a gas (gas coolant) and liquid (liquid coolant), external power of a pump 5 etc. could be made unnecessary. If adopting such a configuration, even if the amount of heat generation of an electronic apparatus increased, it would be possible to forcibly and proactively cool the heat receiver 1 by the mixed working fluid, so compared with cooling the heat receiver 1 by air cooling, the cooling performance can be greatly enhanced.

Due to the pump 5, the mixed working fluid circulates through the inside of a closed loop channel formed by the heat receiver 1, feed channel 2, heat exchanger 3, and return channel 4. In the present embodiment, the heat exchanger 3 is provided with a plurality of heat radiating fins 6. The heat radiating fins 6 are cooled by the cooling air from a blower fan 7 and lower the temperature of the mixed working fluid flowing through the inside of the heat exchanger 3. Further, between the heat generating member 8 and the heat receiver 1, a heat conducting material 9 efficiently transferring the heat generated by the heat generating member 8 to the heat receiver 1 is provided.

For the mixed working fluid sealed in the cooling device 10 of the above such structure, a mixed working fluid comprised of pure water plus ethanol added to give an alcohol concentration of ethanol 0.1 mass % to 5 mass % is used. “Pure water” is water of 100 mass % of degassed distilled water. To this pure water, ethanol is added to prepare a mixed working fluid provided with an alcohol concentration of ethanol 0.1 mass % to 5 mass %. This mixed working fluid is sealed in the circulating cooling water circuit of the cooling device under a vacuum of a vacuum degree of −100 kPa (gauge pressure). Here, the reason for using a mixed working fluid provided with an alcohol concentration of ethanol 0.1 mass % to 5 mass % as the mixed working fluid in this embodiment of the present application will be explained.

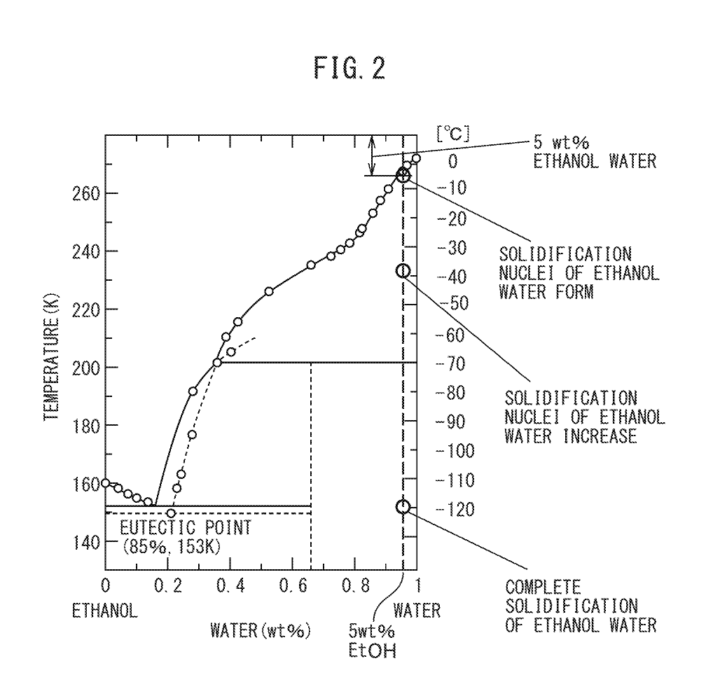

FIG. 2 is an equilibrium diagram illustrating the mixing ratio of the ethanol aqueous solution comprised of pure water plus ethanol and the state of solidification when lowering the temperature for a freezing experiment. The abscissa illustrates the mixing ratio of mass of pure water and ethanol (wt %), the right end of the abscissa illustrates the state of pure water 100%, and the left end of the abscissa illustrates the state of ethanol 100%. Further, the ordinate illustrates the temperature, the left side displays the temperature by Fahrenheit (° K), and the right side displays the temperature by Centigrade (° C.). Note that, in the following explanation, the ethanol aqueous solution will sometimes be simply described as “ethanol water”.

As the ethanol concentration becomes higher, the temperature of the solidification point falls. When crossing the solid phase line at −120° C., the alcohol aqueous solution completely solidifies. Further, when crossing the liquid phase line, at ethanol 30 mass %, the solidification point was −21° C., at ethanol 20 mass %, the solidification point was −11° C., and at ethanol 10 mass %, the solidification point was −4.5° C. Further, it was learned that an ethanol 5 mass % aqueous solution remains stable in a −30° C. subfreezing point environment since even if the water component solidifies, due to the alcohol component of the solution, the mixed working fluid has flexibility as a sherbet-like mass (ice gel). This indicates that even in a −30° C. subfreezing point environment, even if the mixed working fluid expands in volume due to solidification, the stress is dispersed and rupture due to freezing is prevented.

Furthermore, to investigate the freezing state of an ethanol aqueous solution with a low mass % of ethanol, six test tubes were filled with pure water and five types of ethanol aqueous solutions with different concentrations in 3 cm³ amounts. These were allowed to stand in a thermostatic bath held at −30° C. The five types of ethanol aqueous solutions were an ethanol 0.1 mass % aqueous solution, ethanol 0.5 mass % aqueous solution, ethanol 1 mass % aqueous solution, ethanol 5 mass % aqueous solution, and ethanol 10 mass % aqueous solution. As a result, only the test tube containing pure water cracked. Sedimentation due to the fracture of the bottom part was seen. From this experiment, it could be confirmed that with an ethanol 0.1 mass % to 5 mass % ethanol aqueous solution, no rupture by freezing occurs due to the expansion of volume at −30° C.

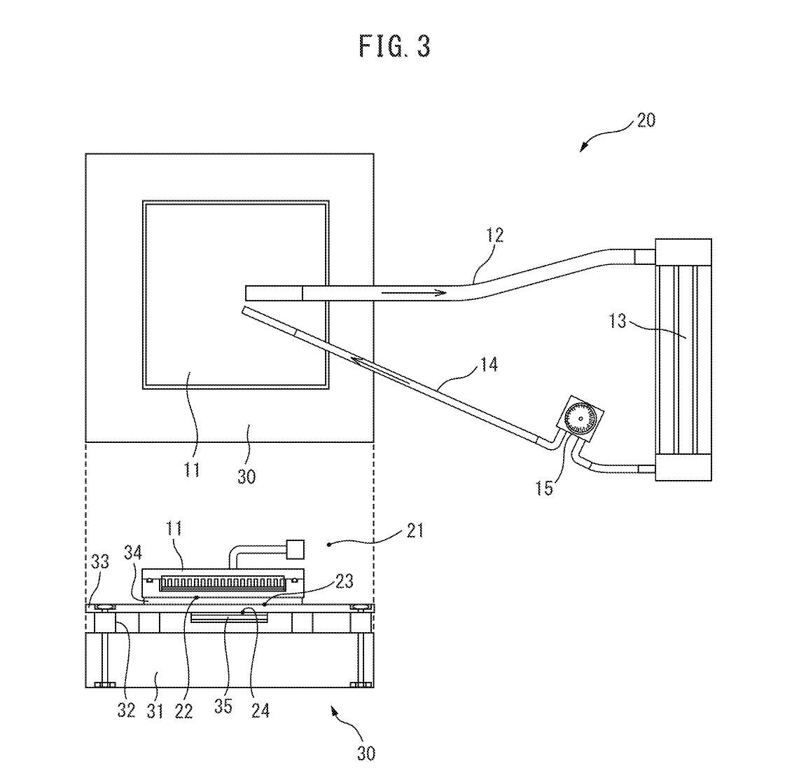

Next, a measurement system of the cooling performance of the cooling device 20 such as illustrated in FIG. 3 was prepared and the cooling performance of the mixed working fluid was investigated. The cooling device 20 was comprised of an evaporator 11, steam pipe 12, radiator 13, liquid pipe 14, and circulating pump 15. Working fluid was circulated through the inside of these. The evaporator 11 was configured by fabricating a 500 W class heat generating module 30 and attaching it to this heat generating module 30. Note that, the radiator 13 is cooled by cooling air from the blower fan so that the cooling device 10 illustrated in FIG. 1 is cooled by the cooling air from the blower fan 7, but illustration of the blower fan is omitted in the cooling device 20 illustrated in FIG. 3.

The heat generating module 30 is attached through heat radiating grease (heat conducting material) 34 on the top surface of a lead 33 attached to the base 31 through spacers 32. Further, at the bottom surface of the lead 33, a heat generating member comprised of the heater 35 was attached. The lead 33 is a heat spreader diffusing the heat of the heater 35. The lead 33 is a rectangular plate with 63 mm sides. The thickness was about 2 mm. The height of the base 31 was 20 mm or so, while the height of the spacer 32 was 5 mm or so. Note that corrosion resistance with the working fluid (ethanol aqueous solution) is necessary, so copper or stainless steel is used for the radiator 13. To maintain the negative pressure of the inside, an air-tight sealed structure is employed.

At this measurement system, the first temperature sensor 21 measures the ambient temperature, the second temperature sensor 22 measures the back surface temperature of the evaporator 11, the third temperature sensor 23 measures the front surface temperature of the lead 33, and the fourth temperature sensor 24 measures the top surface temperature of the heater 35 to thereby investigate the cooling performance of the cooling device 20. Thermocouples may be used for the second to the fourth temperature sensor. The cooling performance of the cooling device 20 can be calculated by the heat resistance of the cooling device, while the heat resistance of the cooling device can, for example, be calculated by (evaporator back surface temperature−ambient temperature)÷(amount of heat generation).

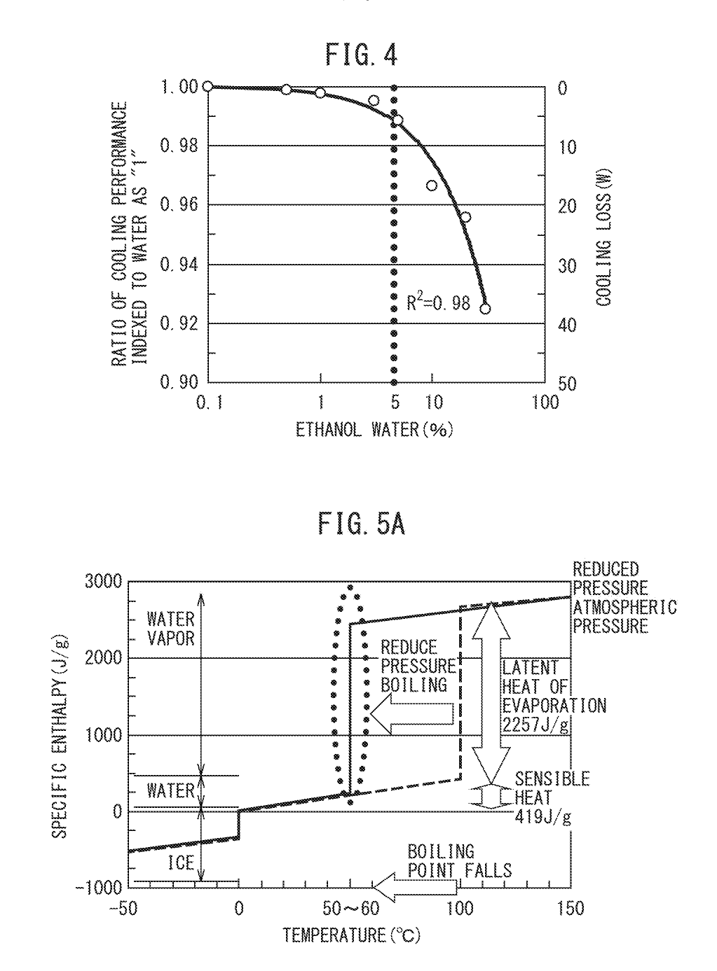

FIG. 4 measures the ratio of cooling performance and the cooling loss when indexed to water as “1” while changing the concentration of the ethanol aqueous solution of water plus ethanol in the measurement system illustrated in FIG. 3. From the measurements, it was learned that with 0.1 to 5 mass % low alcohol concentration ethanol water, the cooling loss was 5 W or less and there was almost no effect on the cooling performance. Due to this, if using 0.1 to 5 mass % low alcohol concentration ethanol water, it is possible to maintain the freezing resistance without impairing the cooling performance. That is, with 0.1 to 5 mass % low alcohol concentration ethanol water, there is no effect on the cooling efficiency. Note that, practically, 1 to 2 mass % low alcohol concentration ethanol water is easy to handle. The cooling loss is also 1 W or less.

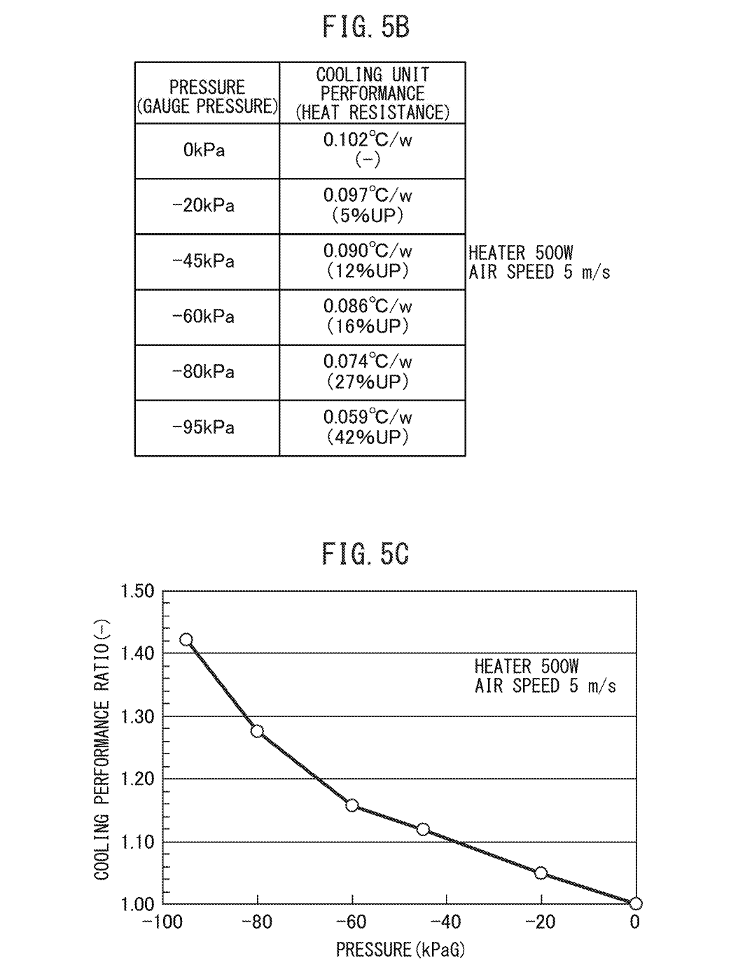

Next, in the measurement system of the cooling performance of the cooling device 20 illustrated in FIG. 3, a specific enthalpy with respect to temperature was investigated by reducing the pressure of the pure water and sealing it in by a saturated steam pressure. FIG. 5A illustrates the relationship of the specific enthalpy to temperature while comparing the atmospheric pressure state and reduced pressure state. In FIG. 5A, the broken line illustrates the atmospheric pressure state, while the solid line illustrates the reduced pressure state. Water boils at 100° C. at atmospheric pressure, but if reducing the pressure and lower the boiling point to 50° C. to 60° C., cooling with a high transport ability of five times water cooling able to applied to high heat generating CPUs becomes possible.

Further, FIG. 5B measures the magnitude of the pressure (gauge pressure) of pressure reduction of the pure water and the cooling unit performance (heat resistance) when making the heater 35 of the cooling device 20 illustrated in FIG. 3 500 W and making the air speed from the cooling fan 5 m/s. Furthermore, FIG. 5C illustrates the ratio of cooling performance corresponding to the pressure (gauge pressure) of pressure reduction of the pure water illustrated in FIG. 5B.

As will be understood from FIG. 5C, the larger the pressure (gauge pressure) of pressure reduction of the pure water, the better the ratio of cooling performance, but there is an inflection point at −60 kPa. −60 kPa to less than −100 kPa can be said to be an effective range. Therefore, in this embodiment, as one example, the reduced pressure state was made −80 kPa. Here, heating 0° C. water to make the water change to water vapor is compared between the atmospheric pressure state and reduced pressure state using FIG. 5A. In the atmospheric pressure state, the water changes to water vapor, so a sensible heat of 419 kJ/kg and latent heat of evaporation of 2257 kJ/kg become necessary. As opposed to this, in the reduced pressure state, as illustrated by the broken lines, the water boils under the reduced pressure and changes to water vapor at 50 to 60° C. For this reason, by utilizing the latent heat of evaporation with the lowered boiling point due to the reduced pressure, larger transport of heat than at the atmospheric pressure state becomes possible.

Further, the latent heat of evaporation of ethanol is 838 kJ/kg or lower compared with the latent heat of evaporation of water, but with 5 mass % or so ethanol water, the latent heat of evaporation does not change that much from water, so a pressure reduction effect is obtained even with a cooling device using 5 mass % or so ethanol water. Note that, ethanol water itself may be used at atmospheric pressure, that is, used without pressure reduction, so long as the conditions are met even with liquid cooling such as with general water cooling.

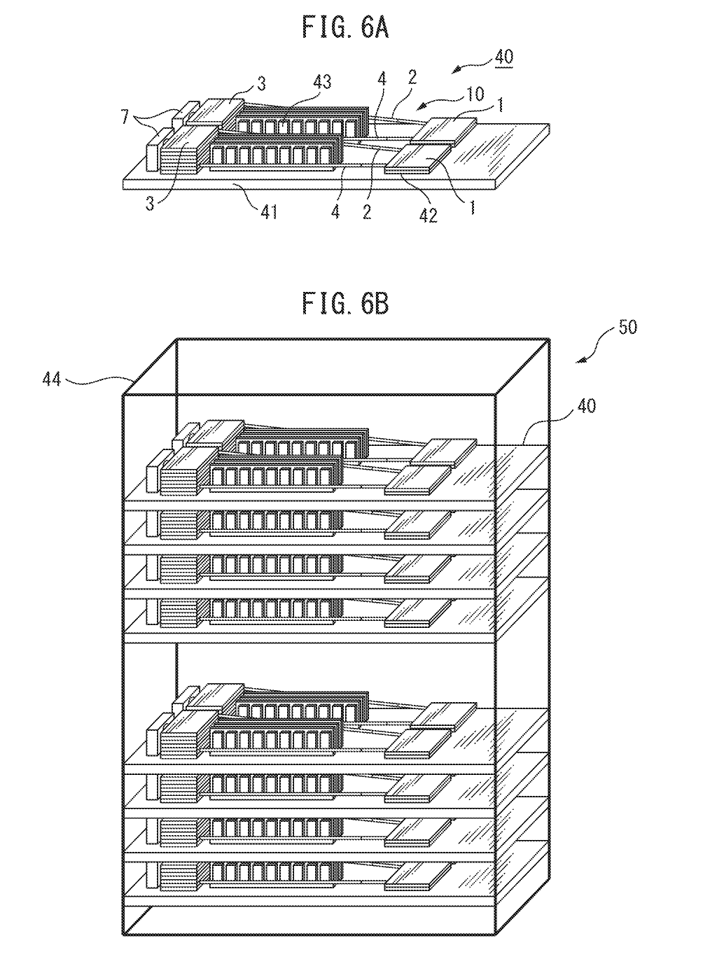

FIG. 6A illustrates the structure of a CPU module 40 to which a cooling device 10 of the present application explained in FIG. 1 is applied. On the printed circuit board 41 of the CPU module 40, package CPUs 42 or memory DIMMs 43 or other heat generating parts are mounted. The cooling devices 10 are arranged on the printed circuit board 41 for cooling these heat generating parts. The heat receivers 1 are attached on the two package CPUs 42. Two each heat exchangers 3 and blower fans 7 are provided at the opposite sides to the mounting positions of the package CPUs 42 on the printed circuit board 41. Further, the heat receivers 1 and the heat exchangers 3 are connected by the feed channels 2 and the return channels 4. Inside, 0.1 to 5 mass % low alcohol concentration ethanol water circulates sealed in a reduced pressure state. A plurality of the CPU modules 40 provided with such a structure are stored in the rack 44 such as illustrated in FIG. 6B whereby an electronic apparatus 50, for example, a server system 50, is formed.

In the above explained embodiments, as the mixed working fluid, low alcohol concentration ethanol water comprised of pure water plus 0.1 to 5 mass % of ethanol is used. On the other hand, as the mixed working fluid, not pure water, but pure water in which additives are mixed (impure water) may be used. As additives, there are, for example, SiO₂, TiO₂, Al₂O₃, and other ceramic nanoparticles, Au, Ag, Cu, Ti, and other metal nanoparticles, and graphene, fullerene, carbon nanotubes, and other nanoparticles.

Therefore, next, an embodiment using low alcohol concentration ethanol water comprised of impure water plus 0.1 to 5 mass % of ethanol as the mixed working fluid will be explained. For the mixed working fluid using impure water as well, measurement was performed in the same way as the embodiment using low alcohol concentration ethanol water comprised of pure water plus 0.1 to 5 mass % of ethanol as the mixed working fluid.

First, a freezing experiment was conducted by the mixing ratio of the ethanol aqueous solution comprised of impure water containing additives plus ethanol and lowered temperature. In this experiment, substantially the same results were obtained as with the freezing experiment with the mixing ratio of the ethanol aqueous solution comprised of pure water plus ethanol explained in FIG. 2 and lowered temperature. That is, it was learned that an aqueous solution of impure water plus ethanol 5 mass % remains stable in a −30° C. subfreezing point environment since even if the water component solidifies, due to the alcohol component of the solution, the mixed working fluid has flexibility as a sherbet-like mass (ice gel). This indicates that even if using impure water, even in a −30° C. subfreezing point environment, even if the mixed working fluid expands in volume due to solidification, the stress is dispersed and rupture due to freezing is prevented.

Furthermore, an experiment was conducted comparing the freezing state of an ethanol 0.1 mass % ethanol aqueous solution containing pure water and impure water. Two test tubes were filled with ethanol 0.1 mass % aqueous solution containing pure water and impure water in 3 cm³ amounts. These were allowed to stand in a thermostatic bath held at −30° C. As a result, both test tubes cracked and sedimentation due to rupture of the bottom parts was also seen. From this experiment, it could be confirmed that even with an ethanol 0.1 mass % ethanol aqueous solution using impure water, no rupture due to freezing occurs due to expansion of volume at −30° C.

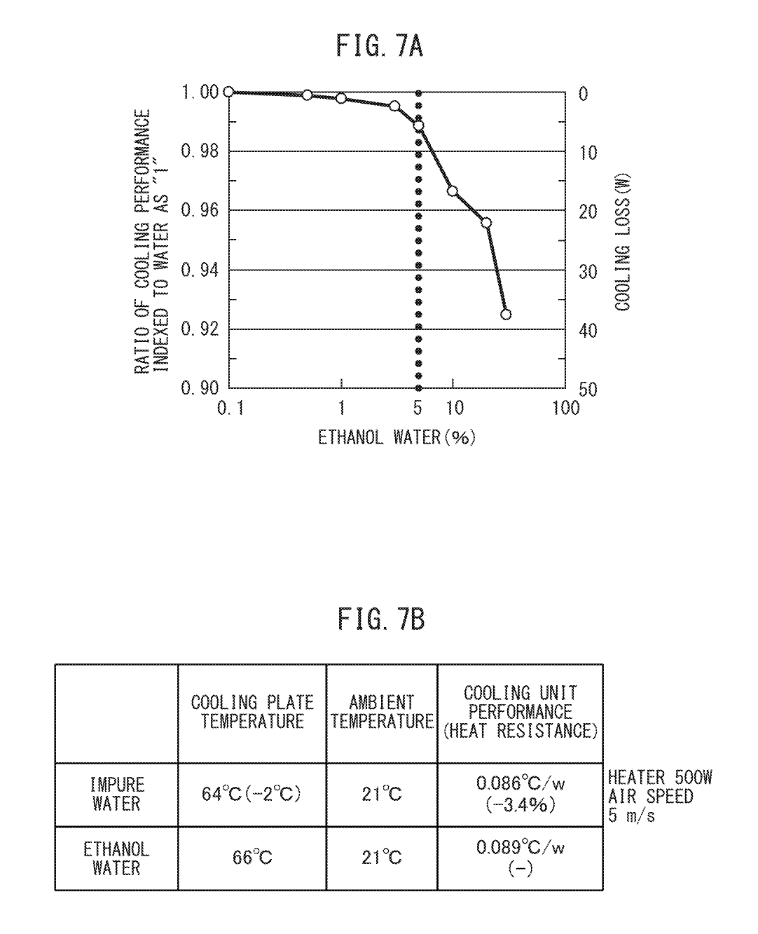

Next, the measurement system of the cooling performance of the cooling device 20 explained in FIG. 3 was used to investigate the cooling performance of a mixed working fluid using impure water. FIG. 7A measures the ratio of cooling performance and the cooling loss when indexed to water as “1” while changing the concentration of the ethanol aqueous solution of impure water plus ethanol in the measurement system illustrated in FIG. 3.

Further, the cooling unit performances (heat resistances) when using pure water and when using impure water were measured when making the heater 35 of the cooling device 20 illustrated in FIG. 3 500 W, making the air speed from the cooling fan 5 m/s, and making the ambient temperature 21° C. The results are illustrated in FIG. 7B. The dimensions of the lead (cooling plate) 33 at this time were 40 mm×10 mm. The “ethanol water” described in FIG. 7B is a working fluid comprised of pure water plus 0.1 to 5 mass % of ethanol, while the “impure water” is a mixed working fluid comprised of pure water plus 0.1 to 5 mass % of ethanol and additives for use as solidification nuclei.

From FIG. 7A and FIG. 7B, it is learned that “impure water” has a cooling loss of 5 W or less and is improved in cooling performance [(cooling plate temperature−ambient temperature)÷(amount of heat generation)] compared with “ethanol water”. Due to this, use of “impure water” enables better cooling performance than “ethanol water” and improved freezing resistance. That is, “impure water” has no effect on the cooling loss and is better in cooling performance than “ethanol water”. The reason why “impure water” is better in cooling performance is that with so-called boiling cooling utilizing the heat of evaporation accompanying the change from the liquid phase to the vapor phase, the additive particles (solidification nuclei) act as boiling nuclei and an effect of promotion of heat conduction is obtained. Note that, practically, 1 to 2 mass % low alcohol concentration “impure water” is easy to handle. The cooling loss is also 1 W or less.

Furthermore, in the measurement system of the cooling performance of the cooling device 20 illustrated in FIG. 3, the specific enthalpy with respect to temperature was investigated by reducing the pressure of the impure water and sealing it in. The same results as the results illustrated in FIG. 5A were obtained. Therefore, even if using “impure water”, by utilizing the latent heat of evaporation with the lowered boiling point due to the reduced pressure, larger transport of heat than at the atmospheric pressure state becomes possible. From the above, the 0.1 to 5 mass % low alcohol concentration “impure water” can also be used for the CPU module 40 illustrated in FIG. 6A.

Note that for the working fluid for heat pipe use described in the above-mentioned Japanese Laid-Open Application Publication No. 2013-224770, a working fluid comprised of pure water plus alcohol with three or more carbon atoms in 0.01 to 20 mass % plus nanoparticles corresponding to the solidification nuclei of the present application is disclosed. This working fluid differs in composition from the “impure water” of the present application. This is because the working fluid disclosed in Japanese Laid-Open Application Publication No. 2013-224770 limits the alcohol to three carbon atoms or more to effectively use Marangoni convection for heat transport. It is a composition for improving the heat transport performance and not a composition for obtaining a freezing resistance. This is clear since alcohol with large numbers of carbon atoms is insoluble in water and antifreezing performance cannot be obtained. As opposed to this, the “impure water” of the present application uses the water soluble ethanol with two carbon atoms and is a composition for preventing freezing, so there is freezing resistance. This greatly differs from the working fluid disclosed in Japanese Laid-Open Application Publication No. 2013-224770.

As explained above, according to the cooling device of the present application when 0.1 to 5 mass % low alcohol concentration “ethanol water” or “impure water” is sealed in as a mixed working fluid, there are the advantageous effects that the mixed working fluid is improved in freezing resistance and the cooling device does not fall in cooling performance.

That is, in the cooling device and the cooling device of an electronic apparatus of the present application, ethanol is added to pure water or an aqueous solution containing an additive to obtain a mixed working fluid provided with an alcohol concentration of ethanol 0.1 mass % to 5 mass % and this is sealed in as a coolant, so there are the advantageous effects that the freezing resistance of the mixed working fluid is improved and the cooling performance of the cooling device and the cooling device of an electronic apparatus does not fall.

All examples and conditional language provided herein are intended for the pedagogical purposes of aiding the reader in understanding the invention and the concepts contributed by the inventor to further the art and are not to be construed as limitations to such specifically recited examples and conditions, nor does the organization of such examples in the specification relate to a illustrating of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling device using a mixed working fluid comprising:
a heat receiver configured to carry a coolant to rob heat from a heat generating member;
a heat exchanger configured to transfer heat from the coolant and lower the coolant in temperature;
a first channel configured to carry the coolant from the heat receiver to the heat exchanger; and
a second channel configured to carry the coolant from the heat exchanger to the heat receiver, wherein the coolant is comprised of pure water and ethanol, and has an alcohol concentration of ethanol 0.1 mass % to 5 mass %.

2. A cooling device using a mixed working fluid comprising:
a heat receiver configured to carry a coolant to rob heat from a heat generating member;
a heat exchanger configured to transfer heat from the coolant and lower the coolant in temperature;
a first channel configured to carry the coolant from the heat receiver to the heat exchanger; and
a second channel configured to carry the coolant from the heat exchanger to the heat receiver, wherein
the coolant is comprised of an aqueous solution containing an additive and ethanol, and has an alcohol concentration of ethanol 0.1 mass % to 5 mass %.

3. The cooling device using a mixed working fluid according to claim 2, wherein the additive is comprised of nanoparticles.

4. The cooling device using a mixed working fluid according to claim 3, wherein the nanoparticles are any of SiO₂, TiO₂, AL₂O₃, and other ceramic nanoparticles, Au, Ag, Cu, Ti, and other metal nanoparticles, and graphene, fullerene, and carbon nanotube nanoparticles.

5. The cooling device using a mixed working fluid according to claim 1, wherein the second channel is provided with a pump configured to make the mixed working fluid move.

6. The cooling device using a mixed working fluid according to claim 1, wherein the channel through which the mixed working fluid runs in the cooling device has the mixed working fluid sealed in it by a saturated vapor pressure in a reduced pressure state.

7. The cooling device using a mixed working fluid according to claim 6, wherein the mixed working fluid is sealed by a saturated vapor pressure in a reduced pressure state of −60 kPa to less than −100 kPa.

8. A cooling device of an electronic apparatus using a mixed working fluid cooling a heat generating member mounted on a printed circuit board, in which cooling device of an electronic apparatus,
the cooling device comprises
a heat receiver attached to the heat generating member and configured to carry a coolant to rob heat from the heat generating member,
a heat exchanger arranged on the printed circuit board,
a fan cooling the heat exchanger by cooling air,
a first channel configured to carry the coolant from the heat receiver to the heat exchanger, and
a second channel configured to carry the coolant from the heat exchanger to the heat receiver,
the coolant comprised of pure water and ethanol, and having an alcohol concentration of ethanol 0.1 mass % to 5 mass %.

9. A cooling device of an electronic apparatus using a mixed working fluid cooling a heat generating member mounted on a printed circuit board, in which cooling device of an electronic apparatus,
the cooling device comprises
a heat receiver attached to the heat generating member and configured to carry a coolant to rob heat from the heat generating member,
a heat exchanger arranged on the printed circuit board,
a fan cooling the heat exchanger by cooling air,
a first channel configured to carry the coolant from the heat receiver to the heat exchanger, and
a second channel configured to carry the coolant from the heat exchanger to the heat receiver,
the coolant comprised of aqueous solution containing an additive and ethanol, and having an alcohol concentration of ethanol 0.1 mass % to 5 mass %.

10. The cooling device of an electronic apparatus using a mixed working fluid according to claim 9, wherein the additive is comprised of nanoparticles.

11. The cooling device of an electronic apparatus using a mixed working fluid according to claim 9, wherein the nanoparticles are any of SiO₂, TiO₂, AL₂O₃, and other ceramic nanoparticles, Au, Ag, Cu, Ti, and other metal nanoparticles, and graphene, fullerene, and carbon nanotube nanoparticles.

12. The cooling device of an electronic apparatus using a mixed working fluid according to claim 8, wherein the second channel is provided with a pump making the mixed working fluid move.

13. The cooling device of an electronic apparatus using a mixed working fluid according to claim 8, wherein the channel through which the mixed working fluid runs in the cooling device has the mixed working fluid sealed in it by a saturated vapor pressure in a reduced pressure state.

14. The cooling device of an electronic apparatus using a mixed working fluid according to claim 13, wherein the mixed working fluid is sealed by a saturated vapor pressure in a reduced pressure state of −60 kPa to less than −100 kPa.
